(19) United States
(12) Patent Application Publication
(10) Pub. No.: US 2025/0056911 A1
(43) Pub. Date: Feb. 13, 2025

(54) CHIP PACKAGE AND MANUFACTURING METHOD THEREOF

(71) Applicant: Xintec Inc., Taoyuan City (TW)

(72) Inventors: Wei-Luen SUEN, Taoyuan City (TW); Chien Wei CHANG, Taoyuan City (TW); Zi-Yu LIAO, Taoyuan City (TW); Jiun-Yen LAI, Taoyuan City (TW); Tsang Yu LIU, Zhubei City (TW)

(21) Appl. No.: 18/751,148

(22) Filed: Jun. 21, 2024

Related U.S. Application Data
(60) Provisional application No. 63/518,721, filed on Aug. 10, 2023.

(51) Int. Cl. H01L 27/146; H01L 21/78; H01L 23/00; H01L 23/498

(52) U.S. Cl. CPC H01L 27/14623; H01L 21/78; H01L 24/32; H01L 27/14632; H01L 27/14687; H01L 23/49816; H01L 2224/32225

(57) ABSTRACT

A chip package includes a semiconductor substrate, a light-transmissive plate, a bonding layer, and a light-shielding layer. The bonding layer is located between the semiconductor substrate and the light-transmissive plate. The semiconductor substrate, the bonding layer, and the light-transmissive plate jointly define a sidewall including a first region and a second region. The first region extends from the semiconductor substrate to the light-transmissive plate, and is recessed relative to the second region. The light-shielding layer covers the sidewall and includes an extending portion, a wide portion, and a narrow portion. The extending portion is located on a surface of the semiconductor substrate facing away from the bonding layer. The wide portion is located on the first region of the sidewall. The narrow portion is located on the second region of the sidewall.

### CROSS-REFERENCE TO RELATED APPLICATION

This application claims priority to U.S. Provisional Application Ser. No. 63/518,721, filed Aug. 10, 2023, which is herein incorporated by reference.

### BACKGROUND

### Field of Invention

The present disclosure relates to a chip package and a manufacturing method of the chip package.

### Description of Related Art

Generally speaking, a chip package for image sensing may use a light-transmissive plate to cover a semiconductor substrate, thereby protecting the sensing area of the semiconductor substrate and allowing light to pass through.

However, the sidewall of a single chip package is mainly produced after the step of dicing the semiconductor substrate and the light-transmissive plate. In other words, the sidewall of the semiconductor substrate and the sidewall of the light-transmissive plate of the chip package are exposed. As a result, not only external noise light can easily enter the sidewall of the semiconductor substrate and the sidewall of the light-transmissive plate to cause interference, but also the sidewall of the chip package is easily damaged due to external force impact. Although some designs can extend a passivation layer used for ball implantation to the sidewall of the semiconductor substrate, the sidewall of the light-transmissive plate still cannot be effectively protected and shielded from light.

### SUMMARY

One aspect of the present disclosure provides a chip package.

According to some embodiments of the present disclosure, a chip package includes a semiconductor substrate, a light-transmissive plate, a bonding layer, and a light-shielding layer. The bonding layer is located between the semiconductor substrate and the light-transmissive plate. The semiconductor substrate, the bonding layer, and the light-transmissive plate jointly define a sidewall including a first region and a second region. The first region extends from the semiconductor substrate to the light-transmissive plate, and is recessed relative to the second region. The light-shielding layer covers the sidewall and includes an extending portion, a wide portion, and a narrow portion. The extending portion is located on a surface of the semiconductor substrate facing away from the bonding layer. The wide portion is located on the first region of the sidewall. The narrow portion is located on the second region of the sidewall.

In some embodiments, the narrow portion of the light-shielding layer is in direct contact with the light-transmissive plate.

In some embodiments, the wide portion of the light-shielding layer is in direct contact with the semiconductor substrate and the bonding layer.

In some embodiments, the bonding layer completely covers a surface of the semiconductor substrate facing toward the bonding layer.

In some embodiments, a material of the bonding layer is optical glue, and a thickness of the bonding layer is in a range from 4 μm to 6 μm.

In some embodiments, the bonding layer surrounds a central region of the semiconductor substrate, such that there is a space among the bonding layer, the semiconductor substrate, and the light-transmissive plate.

In some embodiments, a material of the bonding layer is epoxy resin, and a thickness of the bonding layer is in a range from 30 μm to 50 μm.

In some embodiments, a surface of the narrow portion of the light-shielding layer facing away from the wide portion is coplanar with a surface of the light-transmissive plate facing away from the bonding layer.

In some embodiments, a thickness of the wide portion of the light-shielding layer is in a range from 25 μm to 30 μm, and a thickness of the narrow portion of the light-shielding layer is in a range from 13 μm to 17 μm.

In some embodiments, the chip package further includes an isolation layer, a redistribution layer, and a conductive structure. The isolation layer is disposed along the surface of the semiconductor substrate facing away from the bonding layer. The redistribution layer is located on the isolation layer. The conductive structure is located on the redistribution layer.

In some embodiments, the chip package further includes a passivation layer. The passivation layer is located on the isolation layer and the redistribution layer, and surrounds the conductive structure. The extending portion of the light-shielding layer is covered by the passivation layer.

One aspect of the present disclosure provides a manufacturing method of a chip package.

According to some embodiments of the present disclosure, a manufacturing method of a chip package includes bonding a semiconductor substrate to a light-transmissive plate by using a bonding layer; forming a first opening in the semiconductor substrate and the bonding layer, wherein the first opening extends to the light-transmissive plate; forming a second opening in the light-transmissive plate below the first opening, wherein a thickness of the second opening is less than a thickness of the first opening; forming a light-shielding layer in the first opening and the second opening and extending to a surface of the semiconductor substrate facing away from the bonding layer; forming a groove in the light-shielding layer; and grinding a surface of the light-transmissive plate facing away from the bonding layer until an end of the light-shielding layer in the second opening is removed.

In some embodiments, forming the first opening in the semiconductor substrate and the bonding layer and forming the second opening in the light-transmissive plate below the first opening are performed such that the semiconductor substrate, the bonding layer, and the light-transmissive plate jointly define a sidewall including a first region and a second region, the first region extends from the semiconductor substrate to the light-transmissive plate, and the first region is recessed relative to the second region.

In some embodiments, forming the light-shielding layer in the first opening and the second opening and extending to the surface of the semiconductor substrate facing away from the bonding layer is performed such that the light-shielding layer comprises an extending portion, a wide portion, and a narrow portion, the extending portion is located on the surface of the semiconductor substrate facing away from the bonding layer, the wide portion is located on the first region of the sidewall, and the narrow portion is located on the second region of the sidewall.

In some embodiments, the manufacturing method of the chip package further includes forming an isolation layer disposed along the surface of the semiconductor substrate facing away from the bonding layer; and forming a redistribution layer on the isolation layer.

In some embodiments, the manufacturing method of the chip package further includes forming a passivation layer on the isolation layer, the redistribution layer, and the light-shielding layer; and forming a hole in the passivation layer to expose the redistribution layer.

In some embodiments, the manufacturing method of the chip package further includes forming a conductive structure on the redistribution layer exposed through the hole, wherein the passivation layer surrounds the conductive structure.

In some embodiments, the first opening is formed in the semiconductor substrate and the bonding layer by using a first cutting tool to cut, the second opening is formed in the light-transmissive plate below the first opening by using a second cutting tool to cut, and the first cutting tool is different from the second cutting tool.

In some embodiments, a width of the second cutting tool is less than a width of the first cutting tool.

In some embodiments, the groove is formed in the light-shielding layer by laser grooving.

In the aforementioned embodiments of the present disclosure, since the first opening is formed in the semiconductor substrate and the bonding layer and then the second opening is formed in the light-transmissive plate in the manufacturing method of the chip package, the light-shielding layer can cover the sidewall of the semiconductor substrate and the sidewall of the light-transmissive plate after the light-shielding layer is formed in the first and second openings. Thereafter, the two steps including forming the groove in the light-shielding layer and grinding the light-transmissive plate can replace traditional dicing process. As a result, the chip package having the light-shielding layer that covers the sidewall can be obtained. The chip package not only can prevent external noise light from entering the sidewall of the semiconductor substrate and the sidewall of the light-transmissive plate to cause interference to improve image sensing accuracy, but also can protect the sidewall of the semiconductor substrate and the sidewall of the light-transmissive plate to prevent from being damaged due to external force impact.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a chip package according to one embodiment of the present disclosure.

FIG. 2 to FIG. 7 are cross-sectional views at intermediate stages of a manufacturing method of the chip package of FIG. 1.

FIG. 8 is a cross-sectional view of a chip package according to another embodiment of the present disclosure.

FIG. 9 to FIG. 14 are cross-sectional views at intermediate stages of a manufacturing method of the chip package of FIG. 8.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

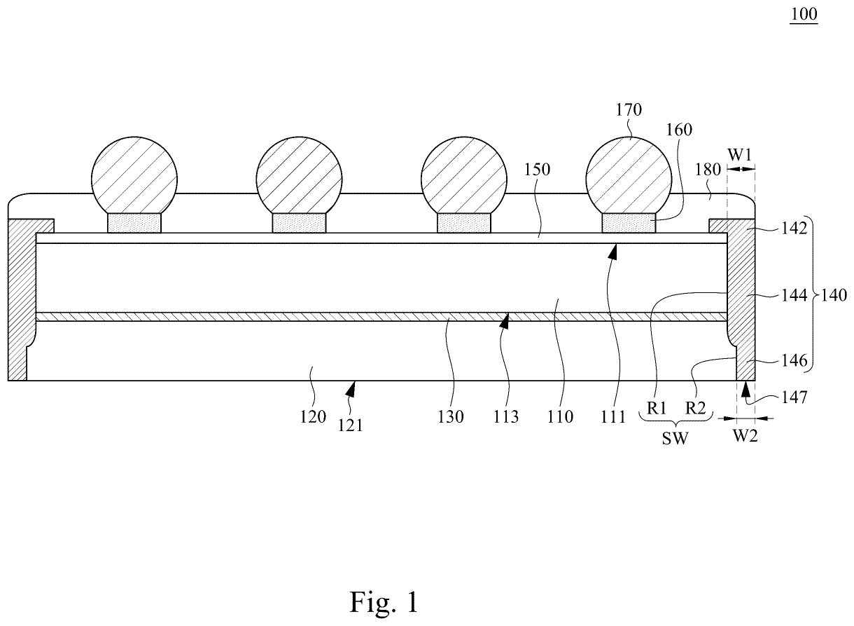

FIG. 1 is a cross-sectional view of a chip package 100 according to one embodiment of the present disclosure. As shown in FIG. 1, the chip package 100 includes a semiconductor substrate 110, a light-transmissive plate 120, a bonding layer 130, and a light-shielding layer 140. The bonding layer 130 is located between the semiconductor substrate 110 and the light-transmissive plate 120. The semiconductor substrate 110, the bonding layer 130, and the light-transmissive plate 120 jointly define a sidewall SW. The sidewall SW includes a first region R1 and a second region R2. The first region R1 extends from the sidewall of the semiconductor substrate 110 to a portion of the sidewall of the light-transmissive plate 120 (e.g., the corner of the top portion of the light-transmissive plate 120), and the entire second region R2 is the sidewall of the light-transmissive plate 120. The first region R1 of the sidewall SW is recessed relative to the second region R2. In other words, the first region R1 of the sidewall SW is closer to the inside, and the second region R2 is closer to the outside. The light-shielding layer 140 covers the sidewall SW and includes an extending portion 142, a wide portion 144, and a narrow portion 146. The extending portion 142 of the light-shielding layer 140 is located on a surface 111 of the semiconductor substrate 110 facing away from the bonding layer 130. The wide portion 144 is located on the first region R1 of the sidewall SW. The narrow portion 146 is located on the second region R2 of the sidewall SW.

In this embodiment, the material of the semiconductor substrate 110 may be silicon, and the thickness of the semiconductor substrate 110 may be in a range from 90 μm to 100 μm (e.g., 95 μm). For example, the semiconductor substrate 110 may be an ambient light sensor or an optical element, which can be applied in augmented reality (AR) or virtual reality (VR). The material of the light-transmissive plate 120 may be glass or the like, and the thickness of the light-transmissive plate 120 may be in a range from 90 μm to 110 μm (e.g., 100 μm). The bonding layer 130 may be optical glue, the thickness of the bonding layer 130 may be in a range from 4 μm to 6 μm (e.g., 5 μm), and the bonding layer 130 completely covers a surface 113 of the semiconductor substrate 110 facing toward the bonding layer 130. The light-shielding layer 140 may be black photoresist.

Since the chip package 100 has the light-shielding layer 140 that covers the sidewall SW, the chip package 100 not only can prevent external noise light from entering the sidewall of the semiconductor substrate 110 and the sidewall of the light-transmissive plate 120 to cause interference to improve image sensing accuracy, but also can protect the sidewall of the semiconductor substrate 110 and the sidewall of the light-transmissive plate 120 to prevent from being damaged due to external force impact and prevent moisture from entering.

In this embodiment, the wide portion 144 of the light-shielding layer 140 is in direct contact with the sidewall of the semiconductor substrate 110 and the sidewall of the bonding layer 130. The narrow portion 146 of the light-shielding layer 140 is in direct contact with the light-transmissive plate 120. A surface 147 of the narrow portion 146 of the light-shielding layer 140 facing away from the wide portion 144 is coplanar with a surface 121 of the light-transmissive plate 120 facing away from the bonding layer 130. In addition, a thickness W1 of the wide portion 144 of the light-shielding layer 140 is in a range from 25 μm to 30 μm (e.g., 27.5 μm), and a thickness W2 of the narrow portion 146 of the light-shielding layer 140 is in a range from 13 μm to 17 μm (e.g., 15 μm).

Moreover, the chip package 100 further includes an isolation layer 150, a redistribution layer 160, a conductive structure 170, and a passivation layer 180. The isolation layer 150 is disposed along the surface 111 of the semiconductor substrate 110 facing away from the bonding layer 130. The redistribution layer 160 is located on the isolation layer 150. The conductive structure 170 is located on the redistribution layer 160. The passivation layer 180 is located on the isolation layer 150 and the redistribution layer 160, and surrounds the conductive structure 170. Furthermore, the extending portion 142 of the light-shielding layer 140 is covered by the passivation layer 180. In some embodiments, the passivation layer 180 may be solder resist green paint, and there is an interface between the passivation layer 180 and the light-shielding layer 140 that has black photoresist material.

In the following description, the manufacturing method of the chip package 100 will be explained.

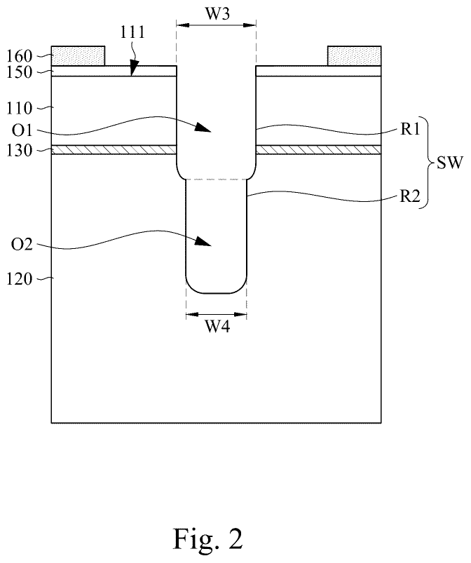

FIG. 2 to FIG. 7 are cross-sectional views at intermediate stages of a manufacturing method of the chip package 100 of FIG. 1, which are an area adjacent to the light-shielding layer 140. The semiconductor substrate 110 and the light-transmissive plate 120 of FIG. 2 to FIG. 6 are a wafer-level size that has not undergone a dicing process. Referring to FIG. 2, the semiconductor substrate 110 is bonded to the light-transmissive plate 120 by using the bonding layer 130. Thereafter, the isolation layer 150 is formed to dispose along the surface 111 of the semiconductor substrate 110 facing away from the bonding layer 130, and the redistribution layer 160 is formed on the isolation layer 150. Subsequently, a first opening O1 is formed in the semiconductor substrate 110 and the bonding layer 130, such that the light-transmissive plate 120 is exposed through the first opening O1. As a result, the first opening O1 may extend to the light-transmissive plate 120. Thereafter, a second opening O2 is formed in the light-transmissive plate 120 below the first opening O1, such that the second opening O2 is communicated with the first opening O1, and is substantially aligned with the first opening O1 in a vertical direction.

In addition, a thickness W4 of the second opening O2 is less than a thickness W3 of the first opening O1. In some embodiments, the first opening O1 is formed in the semiconductor substrate 110 and the bonding layer 130 by using a first cutting tool to cut, the second opening O2 is formed in the light-transmissive plate 120 below the first opening O1 by using a second cutting tool to cut, and the first cutting tool is different from the second cutting tool. The width of the second cutting tool is less than the width of the first cutting tool, thereby enabling the thickness W4 of the second opening O2 to be less than the thickness W3 of the first opening O1.

Through the aforementioned steps for forming the first opening O1 and forming the second opening O2, the semiconductor substrate 110, the bonding layer 130, and the light-transmissive plate 120 jointly define the sidewall SW. The sidewall SW surrounds the first opening O1 and the second opening O2. The sidewall SW includes the first region R1 and the second region R2, the first region R1 extends from the semiconductor substrate 110 to the light-transmissive plate 120, and the first region R1 is recessed relative to the second region R2.

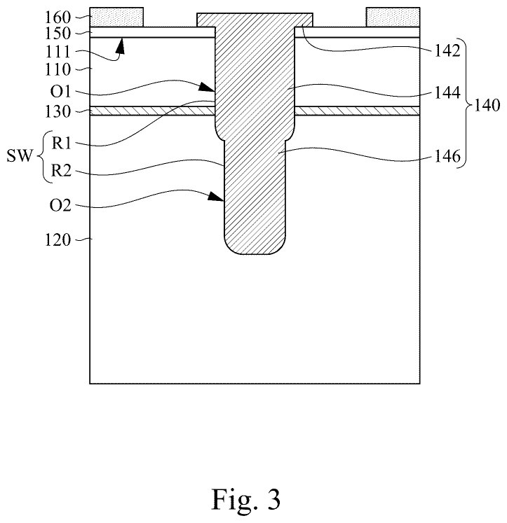

Referring to FIG. 3, after the formations of the first opening O1 and the second opening O2, the light-shielding layer 140 is formed in the first opening O1 and the second opening O2, and the light-shielding layer 140 extends to the surface 111 of the semiconductor substrate 110. The light-shielding layer 140 may be formed by inject process and photolithography process. Through the aforementioned steps for forming the light-shielding layer 140, the light-shielding layer 140 includes the extending portion 142, the wide portion 144, and the narrow portion 146, in which the extending portion 142 is located on the surface 111 of the semiconductor substrate 110, the wide portion 144 is located on the first region R1 of the sidewall SW, and the narrow portion 146 is located on the second region R2 of the sidewall SW.

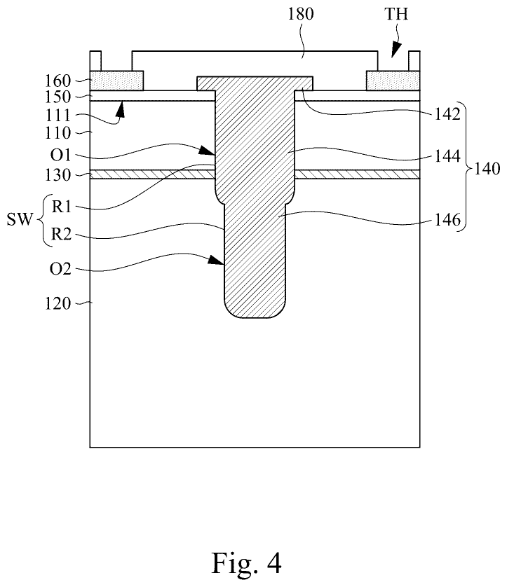

Referring to FIG. 4, after the formation of the light-shielding layer 140, the passivation layer 180 can be formed on the isolation layer 150, the redistribution layer 160, and the light-shielding layer 140, and a hole TH is formed in the passivation layer 180 to expose the redistribution layer 160. The passivation layer 180 covers the top portion of the light-shielding layer 140 (the extending portion 142), and is in contact with the light-shielding layer 140 to form an interface.

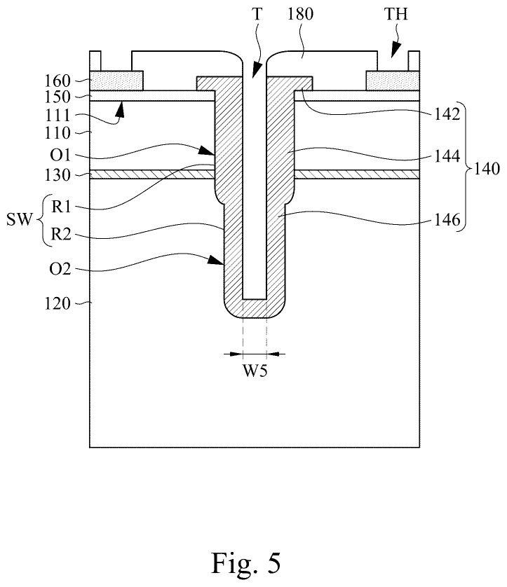

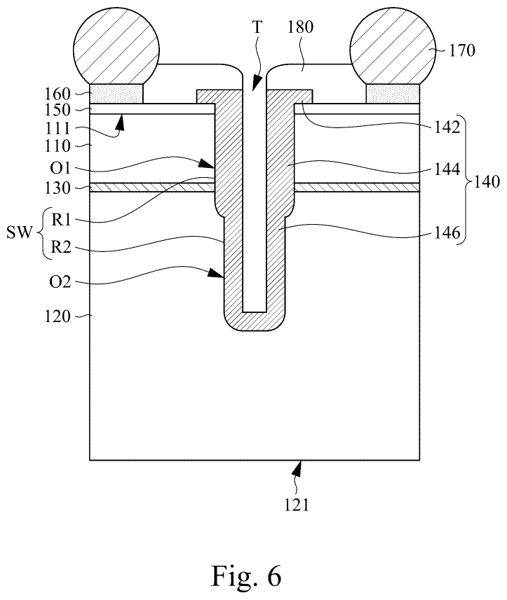

Referring to FIG. 5 and FIG. 6, after the formation of the passivation layer 180 having the hole TH, a groove T can be formed in the light-shielding layer 140. A width W5 of the groove T may be in a range from 8 μm to 12 μm, such as 10 μm. In this embodiment, the groove T is formed by laser grooving. After the formation of groove T, the conductive structure 170 can be formed on the redistribution layer 160 exposed through the hole TH, such that the passivation layer 180 may surround the conductive structure 170. The conductive structure 170 may be sphere (such as solder ball) or cylinder, depending on design requirements.

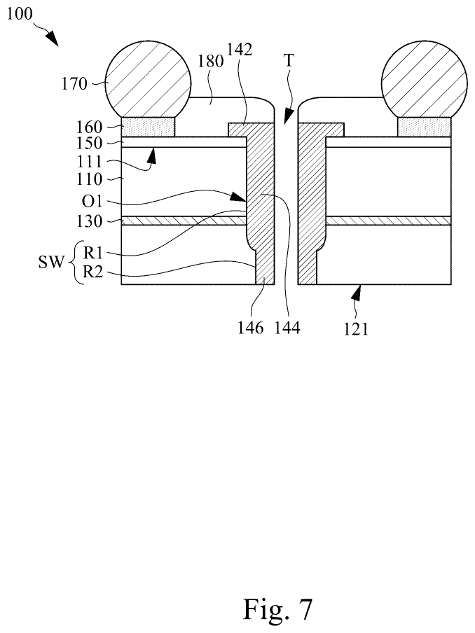

Referring to FIG. 6 and FIG. 7, thereafter, a grinding process is performed on the surface 121 of the light-transmissive plate 120 facing away from the bonding layer 130 until an end (the bottom end) of the light-shielding layer 140 in the second opening O2 of FIG. 6 is removed. As a result, the chip package 100 of FIG. 1 can be obtained.

In summary, since the first opening O1 is formed in the semiconductor substrate 110 and the bonding layer 130 and then the second opening O2 is formed in the light-transmissive plate 120 in the manufacturing method of the chip package 100, the light-shielding layer 140 can cover the sidewall of the semiconductor substrate 110 and the sidewall of the light-transmissive plate 120 after the light-shielding layer 140 is formed in the first and second openings O1 and O2. Thereafter, the two steps including forming the groove T in the light-shielding layer 140 and grinding the light-transmissive plate 120 can replace traditional dicing process, thereby obtaining the chip package 100 having the light-shielding layer 140 that covers the sidewall SW.

It is to be noted that the connection relationships, the materials, and the advantages of the elements described above will not be repeated in the following description. In the following description, another type of a chip package and manufacturing method of the chip package will be explained.

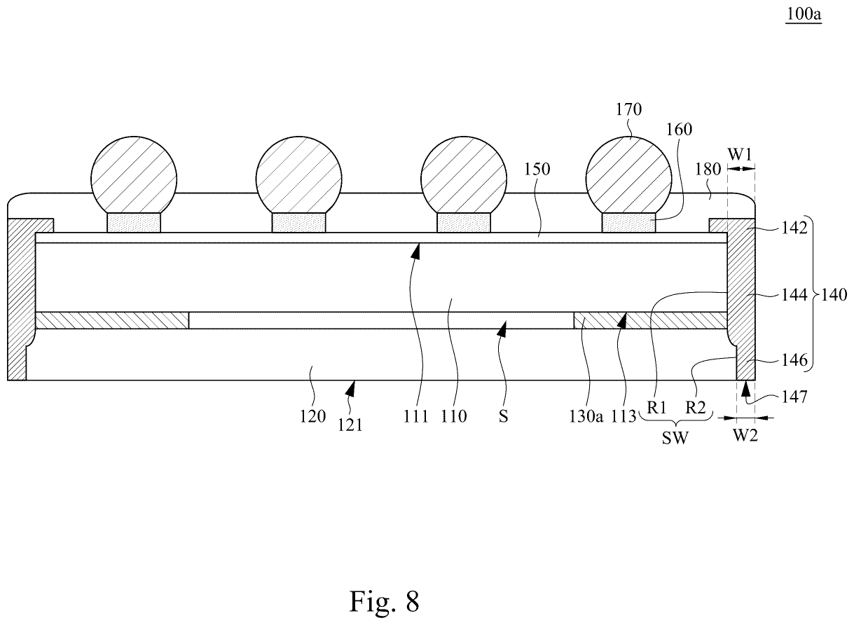

FIG. 8 is a cross-sectional view of a chip package 100a according to another embodiment of the present disclosure. The chip package 100a includes the semiconductor substrate 110, the light-transmissive plate 120, a bonding layer 130a, and the light-shielding layer 140. The difference between this embodiment and the embodiment of FIG. 1 is that the bonding layer 130a surrounds the central region of the semiconductor substrate 110, such that there is a space S among the bonding layer 130a, the semiconductor substrate 110, and the light-transmissive plate 120. Furthermore, the material of the bonding layer 130a may be epoxy resin, and the thickness of the bonding layer 130a is in a range from 30 μm to 50 μm, such as 40 μm. In this embodiment, the bonding layer 130a surrounds the sensing area of the semiconductor substrate 110, and is a supporting layer (dam layer) between the semiconductor substrate 110 and the light-transmissive plate 120.

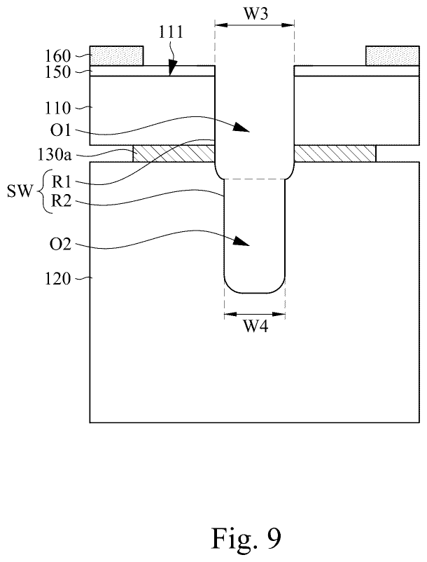

FIG. 9 to FIG. 14 are cross-sectional views at intermediate stages of a manufacturing method of the chip package 100a of FIG. 8, which are an area adjacent to the light-shielding layer 140. The semiconductor substrate 110 and the light-transmissive plate 120 of FIG. 9 to FIG. 13 are a wafer-level size that has not undergone a dicing process. Referring to FIG. 9, the semiconductor substrate 110 is bonded to the light-transmissive plate 120 by using the bonding layer 130a. Thereafter, the isolation layer 150 is formed to dispose along the surface 111 of the semiconductor substrate 110, and the redistribution layer 160 is formed on the isolation layer 150. Subsequently, the first opening O1 is formed in the semiconductor substrate 110 and the bonding layer 130a, such that the light-transmissive plate 120 is exposed through the first opening O1. As a result, the first opening O1 may extend to the light-transmissive plate 120. Thereafter, the second opening O2 may be formed in the light-transmissive plate 120 below the first opening O1, such that the thickness W4 of the second opening O2 is less than the thickness W3 of the first opening O1. The first opening O1 is formed by using a first cutting tool to cut, the second opening O2 is formed by using a second cutting tool to cut, and the width of the second cutting tool is less than the width of the first cutting tool.

Through the aforementioned steps for forming the first opening O1 and forming the second opening O2, the semiconductor substrate 110, the bonding layer 130a, and the light-transmissive plate 120 jointly define the sidewall SW. The sidewall SW surrounds the first opening O1 and the second opening O2. The sidewall SW includes the first region R1 and the second region R2, the first region R1 extends from the semiconductor substrate 110 to the light-transmissive plate 120, and the first region R1 is recessed relative to the second region R2.

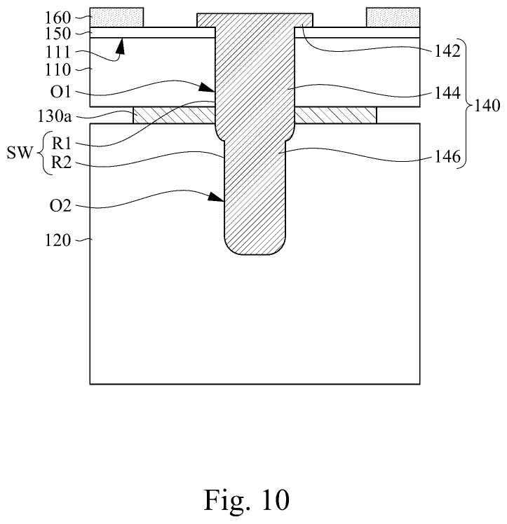

Referring to FIG. 10, after the formations of the first opening O1 and the second opening O2, the light-shielding layer 140 is formed in the first opening O1 and the second opening O2, and the light-shielding layer 140 extends to the surface 111 of the semiconductor substrate 110. In some embodiments, the light-shielding layer 140 may be formed by inject process and photolithography process, such that the light-shielding layer 140 may include the extending portion 142, the wide portion 144, and the narrow portion 146, in which the extending portion 142 is located on the surface 111 of the semiconductor substrate 110, the wide portion 144 is located on the first region R1 of the sidewall SW, and the narrow portion 146 is located on the second region R2 of the sidewall SW.

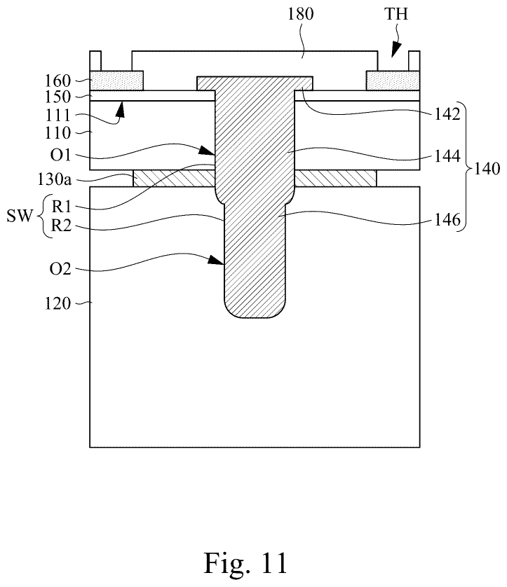

Referring to FIG. 11, after the formation of the light-shielding layer 140, the passivation layer 180 can be formed on the isolation layer 150, the redistribution layer 160, and the light-shielding layer 140, and the hole TH is formed in the passivation layer 180 to expose the redistribution layer 160. The passivation layer 180 covers the light-shielding layer 140.

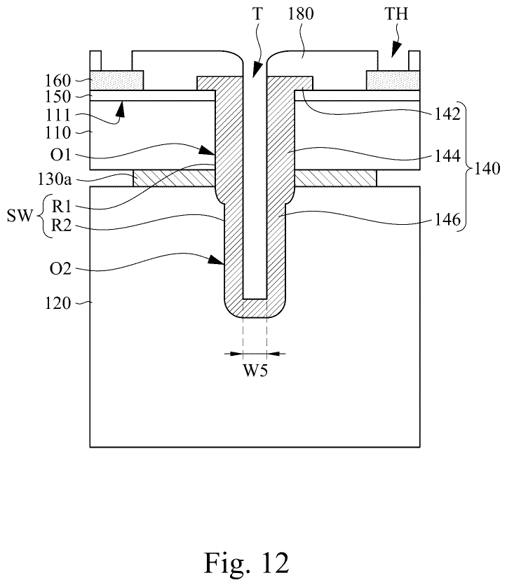

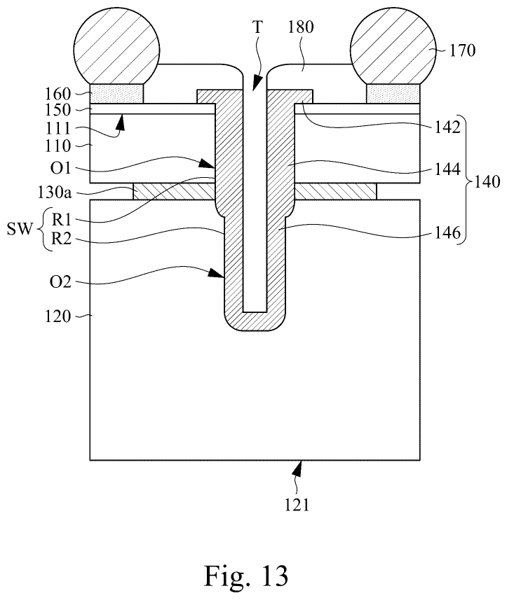

Referring to FIG. 12 and FIG. 13, after the formation of the passivation layer 180 having the hole TH, the groove T can be formed in the light-shielding layer 140. After the formation of the groove T, the conductive structure 170 can be formed on the redistribution layer 160 exposed through the hole TH.

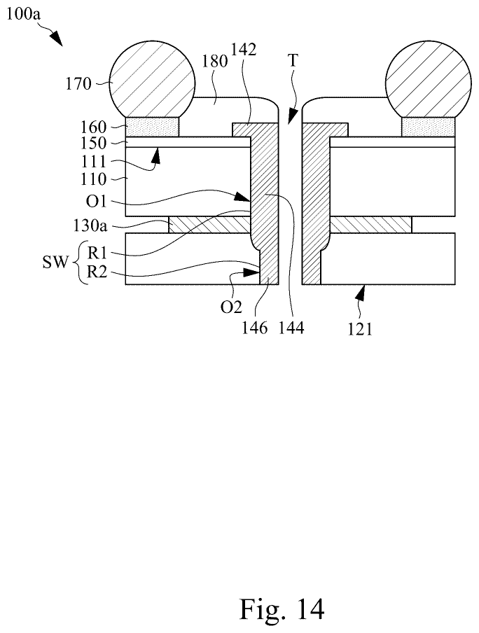

Referring to FIG. 13 and FIG. 14, thereafter, a grinding process is performed on the surface 121 of the light-transmissive plate 120 facing away from the bonding layer 130a until an end (the bottom end) of the light-shielding layer 140 in the second opening O2 of FIG. 13 is removed. As a result, the chip package 100a of FIG. 8 can be obtained.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip package, comprising:
a semiconductor substrate;
a light-transmissive plate;
a bonding layer located between the semiconductor substrate and the light-transmissive plate, wherein the semiconductor substrate, the bonding layer, and the light-transmissive plate jointly define a sidewall including a first region and a second region, the first region extends from the semiconductor substrate to the light-transmissive plate, and the first region is recessed relative to the second region; and
a light-shielding layer covering the sidewall and comprising an extending portion, a wide portion, and a narrow portion, wherein the extending portion is located on a surface of the semiconductor substrate facing away from the bonding layer, the wide portion is located on the first region of the sidewall, and the narrow portion is located on the second region of the sidewall.

2. The chip package of claim 1, wherein the narrow portion of the light-shielding layer is in direct contact with the light-transmissive plate.

3. The chip package of claim 1, wherein the wide portion of the light-shielding layer is in direct contact with the semiconductor substrate and the bonding layer.

4. The chip package of claim 1, wherein the bonding layer completely covers a surface of the semiconductor substrate facing toward the bonding layer.

5. The chip package of claim 4, wherein a material of the bonding layer is optical glue, and a thickness of the bonding layer is in a range from 4 μm to 6 μm.

6. The chip package of claim 1, wherein the bonding layer surrounds a central region of the semiconductor substrate, such that there is a space among the bonding layer, the semiconductor substrate, and the light-transmissive plate.

7. The chip package of claim 6, wherein a material of the bonding layer is epoxy resin, and a thickness of the bonding layer is in a range from 30 μm to 50 μm.

8. The chip package of claim 1, wherein a surface of the narrow portion of the light-shielding layer facing away from the wide portion is coplanar with a surface of the light-transmissive plate facing away from the bonding layer.

9. The chip package of claim 1, wherein a thickness of the wide portion of the light-shielding layer is in a range from 25 μm to 30 μm, and a thickness of the narrow portion of the light-shielding layer is in a range from 13 μm to 17 μm.

10. The chip package of claim 1, further comprising:
an isolation layer disposed along the surface of the semiconductor substrate facing away from the bonding layer;
a redistribution layer located on the isolation layer; and
a conductive structure located on the redistribution layer.

11. The chip package of claim 10, further comprising:
a passivation layer located on the isolation layer and the redistribution layer, and surrounding the conductive structure, wherein the extending portion of the light-shielding layer is covered by the passivation layer.

12. A manufacturing method of a chip package, comprising:
bonding a semiconductor substrate to a light-transmissive plate by using a bonding layer;
forming a first opening in the semiconductor substrate and the bonding layer, wherein the first opening extends to the light-transmissive plate;
forming a second opening in the light-transmissive plate below the first opening, wherein a thickness of the second opening is less than a thickness of the first opening;
forming a light-shielding layer in the first opening and the second opening and extending to a surface of the semiconductor substrate facing away from the bonding layer;
forming a groove in the light-shielding layer; and
grinding a surface of the light-transmissive plate facing away from the bonding layer until an end of the light-shielding layer in the second opening is removed.

13. The manufacturing method of the chip package of claim 12, wherein forming the first opening in the semiconductor substrate and the bonding layer and forming the second opening in the light-transmissive plate below the first opening are performed such that the semiconductor substrate, the bonding layer, and the light-transmissive plate jointly define a sidewall including a first region and a second region, the first region extends from the semiconductor substrate to the light-transmissive plate, and the first region is recessed relative to the second region.

14. The manufacturing method of the chip package of claim 13, wherein forming the light-shielding layer in the first opening and the second opening and extending to the surface of the semiconductor substrate facing away from the bonding layer is performed such that the light-shielding layer comprises an extending portion, a wide portion, and a narrow portion, the extending portion is located on the surface of the semiconductor substrate facing away from the bonding layer, the wide portion is located on the first region of the sidewall, and the narrow portion is located on the second region of the sidewall.

15. The manufacturing method of the chip package of claim 12, further comprising:
forming an isolation layer disposed along the surface of the semiconductor substrate facing away from the bonding layer; and
forming a redistribution layer on the isolation layer.

16. The manufacturing method of the chip package of claim 15, further comprising:
forming a passivation layer on the isolation layer, the redistribution layer, and the light-shielding layer; and
forming a hole in the passivation layer to expose the redistribution layer.

17. The manufacturing method of the chip package of claim 16, further comprising:
forming a conductive structure on the redistribution layer exposed through the hole, wherein the passivation layer surrounds the conductive structure.

18. The manufacturing method of the chip package of claim 12, wherein the first opening is formed in the semiconductor substrate and the bonding layer by using a first cutting tool to cut, the second opening is formed in the light-transmissive plate below the first opening by using a second cutting tool to cut, and the first cutting tool is different from the second cutting tool.

19. The manufacturing method of the chip package of claim 18, wherein a width of the second cutting tool is less than a width of the first cutting tool.

20. The manufacturing method of the chip package of claim 12, wherein the groove is formed in the light-shielding layer by laser grooving.
